(19) United States
(12) Patent Application Publication
(10) Pub. No.: US 2025/0258442 A1
(43) Pub. Date: Aug. 14, 2025

(54) METROLOGY TARGET AND ASSOCIATED METROLOGY METHOD

(71) Applicant: ASML NETHERLANDS B.V, Veldhoven (NL)

(72) Inventors: Maurits VAN DER SCHAAR, Eindhoven (NL); Simon Gijsbert Josephus MATHIJSSEN, Rosmalen (NL); Arie Jeffrey DEN BOEF, Waalre (NL); Vincenzo Giuseppe ZACCA, Eindhoven (NL); Partick WARNAAR, Tilburg (NL)

(73) Assignee: ASML NETHERLANDS B.V, Veldhoven (NL)

(21) Appl. No.: 18/859,145

(22) PCT Filed: Jun. 5, 2023
(86) PCT No.: PCT/EP2023/064955

§ 371 Date: Oct. 22, 2024

(30) Foreign Application Priority Data
Jul. 14, 2022 (EP) 22184952.4

(51) Int. Cl. G03F 7/00

(52) U.S. Cl. CPC G03F 7/706833; G03F 7/70633

(57) ABSTRACT

A substrate including a target. The target including a plurality of sub-targets, the plurality of sub-targets including at least a first sub-target and second sub-target, each of the plurality of sub-targets including at least one subsegmented periodic structure having repetitions of a first region and a second region, wherein at least one of the first regions or second regions comprise subsegmented regions formed of periodic sub-features. The first sub-target includes subsegmentation characteristics for its subsegmented regions and the second sub-target comprises second subsegmentation characteristics for its subsegmented regions, the first subsegmentation characteristics and second subsegmentation characteristics being different in terms of at least one subsegmentation parameter.

### CROSS-REFERENCE TO RELATED APPLICATIONS

This application claims priority of EP application 22184952.4 which was filed on 14 Jul. 2022 and which is incorporated herein in its entirety by reference.

### BACKGROUND

The present invention relates to a metrology apparatus and methods usable, for example, to perform metrology in the manufacture of devices by lithographic techniques.

### FIELD OF THE INVENTION

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

In lithographic processes, it is desirable frequently to make measurements of the structures created, e.g., for process control and verification. Various tools for making such measurements are known, including scanning electron microscopes, which are often used to measure critical dimension (CD), and specialized tools to measure overlay, the accuracy of alignment of two layers in a device. Recently, various forms of scatterometers have been developed for use in the lithographic field. These devices direct a beam of radiation onto a target and measure one or more properties of the scattered radiation—e.g., intensity at a single angle of reflection as a function of wavelength; intensity at one or more wavelengths as a function of reflected angle; or polarization as a function of reflected angle—to obtain a diffraction “spectrum” from which a property of interest of the target can be determined.

Examples of known scatterometers include angle-resolved scatterometers of the type described in US2006033921A1 and US2010201963A1. The targets used by such scatterometers are relatively large, e.g., 40 μm by 40 μm, gratings and the measurement beam generates a spot that is smaller than the grating (i.e., the grating is underfilled). Examples of dark field imaging metrology can be found in international patent applications US20100328655A1 and US2011069292A1 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

An important parameter of interest which may be monitored is overlay, which is a measure of misalignment between patterns in different layers (e.g., zero overlay indicates perfect alignment). Overlay may be monitored by measuring overlay targets designed to have an overlay dependent asymmetry; this asymmetry can be measured by a metrology tool and overlay inferred. A metrology target may comprise a pair of periodic structure or gratings, one grating per relevant layer. As the metrology tool measures structure asymmetry, any non-overlay dependent asymmetry, such as asymmetry in the individual gratings, will manifest as an overlay measurement error. One type of grating asymmetry inherent in subsegmented targets (where individual features or spaces of the target grating is itself segmented) is known as CD imbalance, where the CD of the first one or more features of each target feature is smaller than the nominal feature CD and the CD of the last one or more features of each target feature is larger than the nominal feature CD.

It would be desirable to be able to correct for this CD imbalance.

### SUMMARY OF THE INVENTION

The invention in a first aspect comprises a substrate comprising at least one target, the target comprising a plurality of sub-targets, the plurality of sub-targets comprising at least a first sub-target and second sub-target, each of the plurality of sub-targets comprising at least one subsegmented periodic structure having repetitions of a first region and a second region, wherein at least one of the first regions or second regions comprise subsegmented regions formed of periodic sub-features; wherein said first sub-target comprises first subsegmentation characteristics for its subsegmented regions and said second sub-target comprises second subsegmentation characteristics for its subsegmented regions, the first subsegmentation characteristics and second subsegmentation characteristics being different in terms of at least one subsegmentation parameter.

The invention in a second aspect comprises a method of measuring a parameter of interest comprising: obtaining first measurement data from at least a first sub-target of a target, the at least a first sub-target comprising first subsegmentation characteristics; determining a first parameter of interest value from said first measurement data; obtaining second measurement data from at least a second sub-target of the target, the at least a second sub-target comprising second subsegmentation characteristics, the first subsegmentation characteristics and second subsegmentation characteristics being different in terms of at least one subsegmentation parameter; determining a second parameter of interest value from said second measurement data; and determining a corrected parameter of interest value from said first parameter of interest value and said second parameter of interest value

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus;

FIG. 2 depicts a lithographic cell or cluster in which an inspection apparatus according to the present invention may be used;

FIG. 3 illustrates schematically an inspection apparatus adapted to perform angle-resolved scatterometry and dark-field imaging inspection method;

FIG. 4 illustrates the phenomenon of CD imbalance in a subsegmented grating; and

FIG. 5 is a schematic drawing of an overlay target according to an embodiment.

### DETAILED DESCRIPTION OF EXEMPLARY EMBODIMENTS

Before describing embodiments of the invention in detail, it is instructive to present an example environment in which embodiments of the present invention may be implemented.

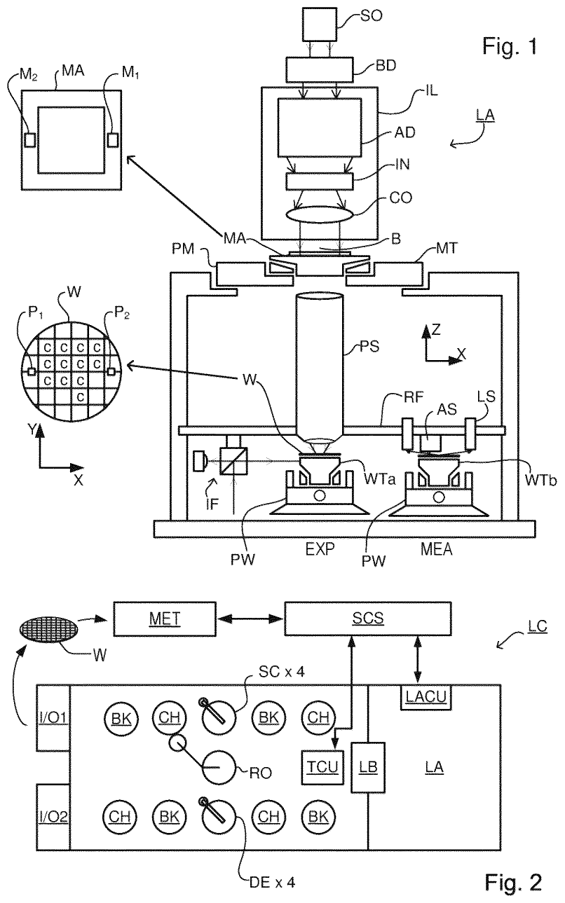

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support holds the patterning device in a manner that depends on the orientation of the patterning device, the design of the lithographic apparatus, and other conditions, such as for example whether or not the patterning device is held in a vacuum environment. The patterning device support can take many forms; the patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., reticle/mask) MA with respect to the path of the radiation beam B, e.g., after mechanical retrieval from a mask library, or during a scan.

Patterning device (e.g., reticle/mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment mark may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

As shown in FIG. 2, the lithographic apparatus LA forms part of a lithographic cell LC, also sometimes referred to a lithocell or cluster, which also includes apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties or parameters of interest such as overlay between subsequent layers, line thicknesses, critical dimensions (CD), etc. Accordingly a manufacturing facility in which lithocell LC is located also includes metrology system MET which receives some or all of the substrates W that have been processed in the lithocell. Metrology results are provided directly or indirectly to the supervisory control system SCS. If errors are detected, adjustments may be made to exposures of subsequent substrates, especially if the inspection can be done soon and fast enough that other substrates of the same batch are still to be exposed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

Within metrology system MET, an inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it is desirable that the inspection apparatus measure properties in the exposed resist layer immediately after the exposure. However, the latent image in the resist has a very low contrast—there is only a very small difference in refractive index between the parts of the resist which have been exposed to radiation and those which have not—and not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of faulty substrates but may still provide useful information.

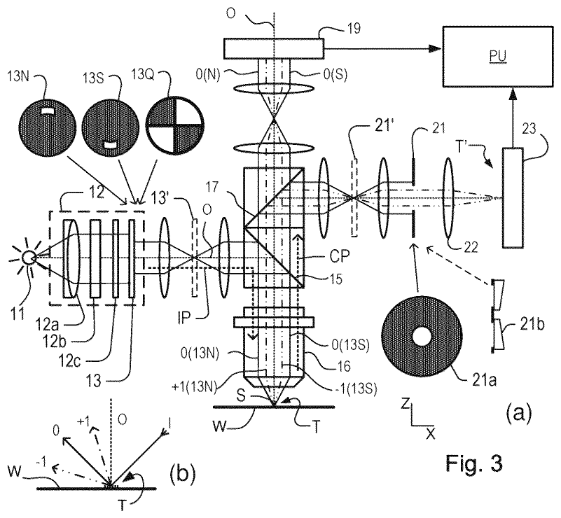

A metrology apparatus suitable for use in embodiments of the invention is shown in FIG. 3(a). Note that this is only one example of a suitable metrology apparatus. An alternative suitable metrology apparatus may use EUV radiation such as, for example, that disclosed in WO2017/186483A1. Many other types of metrology apparatuses are known and may equally be used to implement the concepts disclosed herein. A target structure T and diffracted rays of measurement radiation used to illuminate the target structure are illustrated in more detail in FIG. 3(b). The metrology apparatus illustrated is of a type known as a dark field metrology apparatus. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source 11 (e.g., a xenon lamp) is directed onto substrate W via a beam splitter 15 by an optical system comprising lenses 12, 14 and objective lens 16. These lenses are arranged in a double sequence of a 4F arrangement. A different lens arrangement can be used, provided that it still provides a substrate image onto a detector, and simultaneously allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis from a direction designated, for the sake of description only, as ‘north’. In a second illumination mode, aperture plate 13S is used to provide similar illumination, but from an opposite direction, labeled ‘south’. Other modes of illumination are possible by using different apertures. A specific alternative, aperture plate 13Q comprises a quartered illumination aperture where illumination is admitted via two diagonally opposed quadrants, the other two quadrants being blocked (the illumination and blocked quadrants may be swapped over from those shown). Such an arrangement may be used for simultaneous imaging of the +1 and −1 diffraction orders, and is described further in the aforementioned US2010201963A1. The rest of the pupil plane is desirably dark as any unnecessary light outside the desired illumination mode will interfere with the desired measurement signals.

As shown in FIG. 3(b), target structure T is placed with substrate W normal to the optical axis O of objective lens 16. The substrate W may be supported by a support (not shown). A ray of measurement radiation I impinging on target structure T from an angle off the axis O gives rise to a zeroth order ray (solid line 0) and two first order rays (dot-chain line +1 and double dot-chain line −1), hereafter referred to as a pair of complementary diffraction orders. It should be noted that the pair of complementary diffraction orders may be any higher order pair; e.g., the +2, −2 pair etc. and is not limited to the first order complementary pair. It should be remembered that with an overfilled small target structure, these rays are just one of many parallel rays covering the area of the substrate including metrology target structure T and other features. Since the aperture in plate 13 has a finite width (necessary to admit a useful quantity of light, the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the grating pitches of the target structures and the illumination angles can be designed or adjusted so that the first order rays entering the objective lens are closely aligned with the central optical axis. The rays illustrated in FIGS. 3(a) and 3(b) are shown somewhat off axis, purely to enable them to be more easily distinguished in the diagram.

At least the 0 and +1 orders diffracted by the target structure T on substrate W are collected by objective lens 16 and directed back through beam splitter 15. Returning to FIG. 3(a), both the first and second illumination modes are illustrated, by designating diametrically opposite apertures labeled as north (N) and south (S). When the incident ray I of measurement radiation is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the −1 diffracted rays (labeled 1(S)) are the ones which enter the lens 16.

A second beam splitter 17 divides the diffracted beams into two measurement branches. In a first measurement branch, optical system 18 forms a diffraction spectrum (pupil plane image) of the target structure on first sensor 19 (e.g. a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements of the first order beam. The pupil plane image can also be used for many measurement purposes such as reconstruction.

In the second measurement branch, optical system 20, 22 forms an image of the target structure T on sensor 23 (e.g. a CCD or CMOS sensor). In the second measurement branch, an aperture stop 21a is provided in a plane 21 that is conjugate to the pupil-plane. Aperture stop 21a functions to block the zeroth order diffracted beam so that the image of the target formed on sensor 23 is formed only from the −1 or +1 first order beam. Instead of a simple aperture stop 21a, the metrology tool may use instead a wedge arrangement 21b which separates the first orders and zeroth order, so that they can be imaged separately (apart) on the detector 23. Such an arrangement is described in the aforementioned US2011102753A1 and can be used (e.g., in combination with quartered illumination aperture 13Q) to simultaneously acquire +1 and −1 diffraction orders in one or both directions of the substrate plane.

The images captured by sensors 19 and 23 are output to processor PU which processes the image, the function of which will depend on the particular type of measurements being performed. Note that the term ‘image’ is used here in a broad sense. An image of the grating lines as such will not be formed, if only one of the −1 and +1 orders is present.

Position errors may occur due to an overlay error (often referred to as “overlay”). The overlay is the error in placing a first feature during a first exposure relative to a second feature during a second exposure. The lithographic apparatus minimizes overlay by aligning each substrate accurately to a reference prior to patterning, e.g., by measuring positions of alignment marks on the substrate using an alignment sensor; and by using feedback corrections for the exposure process; e.g., based on measuring overlay on metrology targets post-exposure using a suitable metrology tool such as illustrated in FIG. 3(a).

One known metrology method which may be performed using a metrology tool such as illustrated in FIG. 3(a) is known as diffraction based overlay (DBO) or micro-diffraction based overlay (μDBO). Such μDBO techniques use the imaging branch (detector 23) of the metrology tool. Each of the main “images” used for parameter of interest inference are formed only from a respective higher (e.g., first) diffraction order and as such will now show resolved patterns but rather a region having a certain intensity level. The zeroth order (specular radiation) is typically blocked or diverted elsewhere (e.g., to another part of the detector for monitoring purposes); it is not used directly in μDBO metrology. Asymmetry in a structure such as a μDBO target may be determined from an intensity asymmetry or intensity difference between a complementary pair of diffraction orders (typically a complementary pair of first diffraction orders, i.e., the +1 order and −1 order as illustrated in FIG. 3(b), although +2/−2 or higher orders may technically be used). As such, a first intensity value may be obtained from an image formed from the +1 order and a second intensity value may be obtained from −1 order; with the difference of these intensity values used to calculate an asymmetry of the structure. An overlay target may comprise two overlaid periodic structures or gratings in different layers, such that any overlay (i.e., a misalignment between layers) will result in a misalignment of the two gratings, which manifests as an asymmetry of the target as a whole (deliberate offsets may be provided between the two overlaid gratings to correct for certain target asymmetries). This target asymmetry and therefore overlay can therefore be measured using the techniques just described.

An alternative overlay metrology method is known as continuous DBO or cDBO, where the measured asymmetry signal may be a phase difference asymmetry from a pair of complementary sub-targets (“M pad” and “W pad”) rather than the intensity asymmetry just described. More specifically, in cDBO. an asymmetry signal A may be defined as the phase difference between a diffraction order from an “M pad” and a corresponding diffraction order from a “W pad”, optionally averaged over both diffraction orders of a complementary diffraction order pair: e.g., A=(ϕ_{M}−ϕ_{W})₊₁+(ϕ_{M}−ϕ_{W})₋₁, where (ϕ_{M}−ϕ_{W})₊₁, (ϕ_{M}−ϕ_{W})₋₁ are the measured phase difference between the “M pad” and “W pad” of the +1 diffraction order and −1 diffraction order respectively. As such, it can be appreciated that the concepts described herein are applicable to different types of asymmetry signal. The principle of cDBO is described in Matsunobu et al, Novel diffraction-based overlay metrology utilizing phase-based overlay for improved robustness, Proc. SPIE 11611, Metrology, Inspection, and Process Control for Semiconductor Manufacturing XXXV, 1161126 (22 Feb. 2021), which is incorporated herein by reference.

Like a μDBO target, a cDBO target comprises overlaid periodic structures or gratings in respective layers for which an overlay value is to be measured. Instead of the gratings having the same pitch in the two layers like a μDBO target, cDBO targets comprise sub-targets each having gratings of different pitches in the two layers. More specifically a typical cDBO target comprises an arrangement of two different types of sub-targets (e.g., per direction): an “M pad” or “M sub-grating” which comprises a bottom grating having a smaller pitch than a top grating, with a “W pad” or “W sub-grating” which has these gratings reversed (i.e., it has the same pitches as the M pad but with the larger pitch in the top layer).

Overlay metrology assumes that the gratings used in the targets are strictly symmetrical. Under that assumption, the true overlay is proportional to the measured intensity asymmetry. In reality there are many processes causing the gratings of the overlay target to be asymmetric, e.g. Chemical mechanical polishing (CMP), Etch, Deposition etc.

To be measurable using present optical metrology technology (e.g., a scatterometer such as described above), the measurable pitch or main pitch of an target grating may be orders of magnitude larger than the pitch and/or CD or product features (the actual functional device features). It is often desirable to segment the target gratings with product-like features to avoid damage to target gratings and/or contamination of the device area as a consequence of wafer processing steps such as polishing, deposition or etch. Such product-like features may comprise features of a similar size and/or resolution than the product features (e.g., having a critical dimension (CD) of the same order of magnitude than the CD of the product features). Such target gratings may be referred to as subsegmented target gratings which comprise a subsegmentation of either the lines (first regions) and/or spaces (second regions) of the target grating. The periodic structure or grating defined by these first regions and second regions may form a metrology tool-resolvable pitch, e.g., resolvable by a scatterometer such as those described above. For example, either each line or each space may be segmented so as to comprise periodic sub-features, e.g., a periodic (1D) array of multiple features having a product-magnitude CD and/or pitch.

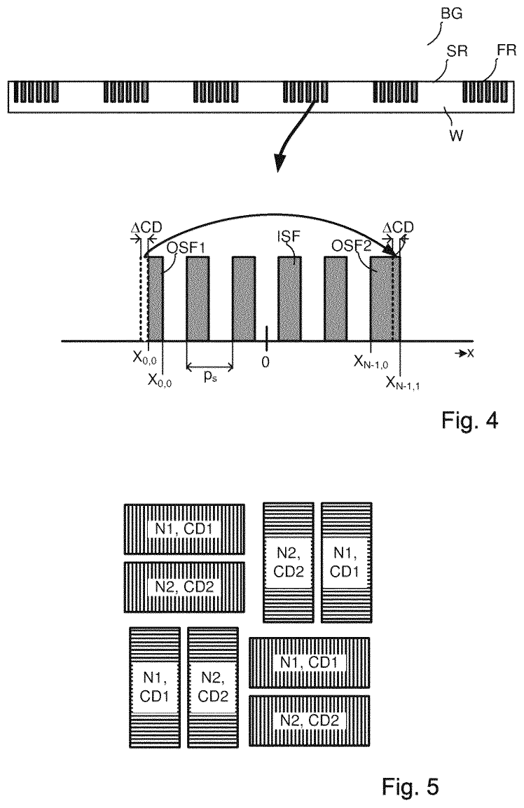

FIG. 4 illustrates a specific type of unwanted grating asymmetry addressed by the concepts described herein, which is sometimes referred to as CD-imbalance. CD-imbalance is particularly applicable to subsegmented targets, e.g., targets formed from one or more subsegmented gratings. The Figure shows a bottom grating BG of a target (e.g., a μDBO target or cDBO target) comprising a series of features (first regions FR) and/or spaces (second regions SR). Each of the features and/or first regions FR (though it may be the second regions) is segmented into sub-features to SF form the subsegmented mark. Detail of a single segmented feature is shown in the drawing.

It should be appreciated that the segmentation may be of the features/first regions only, the spaces/second regions only, or both of the lines/first regions and spaces/second regions. In the latter case, the segmentation may be such that the “spaces” comprise periodic substructures comprising a periodic array of multiple features, each having a CD smaller than the multiple features comprised within the “lines” of the target (which also comprise periodic substructures) and therefore different optical characteristics. Note that subsegmentation is not necessarily 1D periodic. Other examples of subsegmentation include contact array, staggered contact, tilted lines or any other subsegmented structure. The actual form of the subsegmentation is not important.

Each of the sub-features is designed to have the same width or CD (i.e., sub-feature width in the direction of periodicity of the grating labeled X). The inner sub-features ISF, i.e., all but the outermost two sub-features OSF1, OSF2 (i.e., the first sub-feature OSF1 and last sub-feature OSF2) typically do have substantially the same CD. The two (or more) outermost sub-features however can have a different CD; more specifically the first sub-feature of the feature has a CD smaller than the inner sub-features by a CD difference ΔCD, taken from the feature's first outermost edge, and the last sub-feature of the grating BG has a CD larger than the inner sub-features by the same CD difference ΔCD, added to the feature's second outermost edge. This is as if an outer edge portion of the first sub-feature OSF1 was taken from the first sub-feature and added to the outer edge of the last sub-feature OSF2. More features than the two outermost features may be affected in this way; however the outermost features are the most dominantly affected. The number of features affected is not important to the concepts disclosed herein. This CD difference is present due to optical/processing disturbances. Ideally all CDs are the same.

This type of asymmetry causes an overlay measurement error (an error in measurement of overlay). The inventors have quantified this error as follows. Referring again to FIG. 4, the leftmost or first sub-feature has edges at locations x_{0,0} and x_{0,1} and rightmost or last sub-feature has edges at locations x_{N-1,0} and x_{N-1,1}, where:

$${x}_{0 , 0} = - ( \frac{N - 1}{2} ) {p}_{s} - \frac{CD}{2} + Δ CD \\ {x}_{0 , 1} = - ( \frac{N - 1}{2} ) {p}_{s} + \frac{CD}{2} \\ {x}_{N - 1 , 0} = ( \frac{N - 1}{2} ) {p}_{s} - \frac{CD}{2} \\ {x}_{N - 1 , 1} = ( \frac{N - 1}{2} ) {p}_{s} + \frac{CD}{2} + Δ CD$$

where CD is the (intended) CD, N is the number of sub-features comprised in each feature (region) and pₛ is the sub-segmentation pitch (pitch of the sub-features).

Calculating an optical center of gravity CoG of the feature as modeled yields:

$$CoG = \frac{\int xR ( x ) dx}{\int R ( x ) dx} = \frac{( ( N - 1 ) {p}_{s} + CD ) Δ CD}{N \times CD} = ( ( \frac{N - 1}{2} ) \frac{{p}_{s}}{CD} + \frac{1}{N} ) Δ CD$$

Over a sufficiently high number of sub-features N, this may be approximated to:

$$CoG \approx ( \frac{{p}_{s}}{CD} ) Δ CD$$

Therefore the impact of CD imbalance on overlay error becomes greater for more isolated sub-features.

To address this CD imbalance, a target arrangement and method of measuring overlay using such a target arrangement is proposed. The target arrangement and method enables an overlay value to be measured which has been corrected for the effect of CD imbalance in the target grating.

The proposed target concept comprises a plurality of sub-targets, the plurality of sub-targets comprising at least a first sub-target and second sub-target, each of the plurality of sub-targets comprising at least one subsegmented periodic structure having repetitions of a first region and a second region, wherein the first regions or second regions comprise periodic sub-features; wherein said first sub-target comprises first subsegmentation characteristics and said second sub-target comprises second subsegmentation characteristics, the first subsegmentation characteristics and second subsegmentation characteristics being different in terms of at least one subsegmentation parameter.

The proposed target concept comprises a target having at least a first pad-type or sub-target-type comprising at least one (e.g., bottom) periodic structure or grating having first subsegmentation characteristics and a second pad-type or sub-target-type comprising at least one (e.g., bottom) periodic structure or grating having second subsegmentation characteristics. The first subsegmentation characteristics may comprise a first number N₁ of sub-features per first region or second region (e.g., per line or space) and a first sub-feature CD or sub-feature width CD₁ and the second subsegmentation characteristics may comprise a second number N₂ of sub-features per first region or second region and a second sub-feature CD or sub-feature width CD₂, where N₁≠N₂ and/or CD₁≠CD₂. As such, it should be appreciated that only one of the number of sub-features or the sub-feature CD needs to differ between the sub-target type.

In an embodiment, the target may comprise a first pair of sub-targets comprising each of these two sub-target types (e.g., said first target and second target) and a second pair of sub-targets comprising each of these two sub-target types (e.g., a third target having the first subsegmentation characteristics and a fourth target having the second subsegmentation characteristics).

In a μDBO embodiment for example, each of these pairs of sub-targets may have a different bias as is well known in μDBO metrology (strictly only one pair requires a bias such that there is a bias difference between the two pairs). In a typical arrangement, the respective biases for each pair may be equal in magnitude and opposite in direction.

In an embodiment, the target may comprise at least one of the first target types and at least one of the second target types per measurement direction (e.g., X-pads and Y-pads). In an embodiment, the target may comprise said first pair of sub-targets and said second pair of sub-targets per measurement direction (e.g., 8 sub-targets total).

FIG. 5 is a schematic drawing of a target as according to the immediately preceding example. Instead of having two pads or sub-targets per measurement direction as used in μDBO, the target here comprises four pads or sub-targets per measurement direction (eight sub-targets total). Per direction, each of a first pair of sub-targets and a second pair of sub-targets comprises a first sub-target type having first subsegmentation characteristics N₁, CD₁ and a second sub-target type having second subsegmentation characteristics N₂,CD₂, where N₁≠N₂ and/or CD₁≠CD₂. For each direction, the first pair of sub-targets may have a first bias (e.g., +d) and the second pair of sub-targets may have a second bias (e.g., −d).

Using the equation for center of gravity described above, it can be seen that:

$${OV}_{true} - {OV}_{measured 1} = {CoG}_{1} = ( ( \frac{{N}_{1} - 1}{{N}_{1}} ) \frac{{P}_{s 1}}{{CD}_{1}} + \frac{1}{{N}_{1}} ) Δ CD = A * Δ CD \\ {OV}_{true} - {OV}_{measured 2} = {CoG}_{2} = ( ( \frac{{N}_{2} - 1}{{N}_{2}} ) \frac{{P}_{s 2}}{{CD}_{2}} + \frac{1}{{N}_{2}} ) Δ CD = B * Δ CD$$

where OV_{measured1} is the overlay measured using the first sub-target type and OV_{measured2} is the overlay measured using the second sub-target type. The unknowns are the true overlay (parameter of interest) OVₜᵣᵤₑ and the CD imbalance ΔCD. As such, the target design yields sufficient information for two equations, from which the true overlay OVₜᵣᵤₑ can be calculated according to:

$${OV}_{true} = \frac{B * {OV}_{measured 1} - A * {OV}_{measured 2}}{B - A}$$

Each of the measured overlay values OV_{measured1}, OV_{measured2} may be obtained using standard μDBO intensity asymmetry metrology. For example, OV_{measured1} may be measured from an intensity asymmetry measurement from a first sub-target of first sub-target type and OV_{measured2} may be measured from a second sub-target of second sub-target type.

Alternatively, assuming a target such as illustrated in FIG. 5, OV_{measured1} may be measured from a first pair of intensity asymmetry measurements from a first sub-target type from the first pair of sub-targets and from a first sub-target type from the second pair of sub-targets, while OV_{measured2} may be measured from a second sub-target type from the first pair of sub-targets and from a second sub-target type from the second pair of sub-targets. Taking into account the different bias between the first pair and second pair of sub-targets, correction may be made for other target asymmetries in obtaining overlay values OV_{measured1}, OV_{measured2}, prior to performing the correction for CD-imbalance proposed. While these first corrections (to obtain overlay values OV_{measured1},OV_{measured2}) may potentially also correct (partially) for the impact of CD-imbalance, it can be assumed that the target asymmetry correction will capture the CD-imbalance similarly (with equal efficiency) for both sub-targets. Therefore, these should cancel in determining OVₜᵣᵤₑ according to the equation above such that any double-correction is prevented.

It has been shown that the assumptions on which these concepts are based, e.g., ΔCD is the same for both sub-target types and that the CoG is a proxy for the measured overlay, is sufficiently correct.

It can be appreciated that the same basic concept is equally applicable to cDBO metrology and cDBO target types. Such an approach may use, (e.g., optionally per direction), a first pair of sub-targets comprising two M sub-targets and a second pair of sub-targets comprising two W sub-targets. The first pair of sub-targets may comprise a first M sub-target type having first subsegmentation characteristics for at least one of its gratings and a second M sub-target type having second subsegmentation characteristics for at least one of its gratings. Similarly, the second pair of sub-targets may comprise a first W sub-target type having first subsegmentation characteristics for at least one of its gratings and a second W sub-target type having second subsegmentation characteristics for at least one of its gratings. In such a case, the delta fringe position (measured phase difference) is now directly related to the center of gravity delta between the different sub-target types, but with Moiré amplification.

Further embodiments according to the present invention are described in below numbered clauses:
1. A substrate comprising at least one target, the target comprising a plurality of sub-targets, the plurality of sub-targets comprising at least a first sub-target and second sub-target, each of the plurality of sub-targets comprising at least one subsegmented periodic structure having repetitions of a first region and a second region, wherein at least one of the first regions or second regions comprise subsegmented regions formed of periodic sub-features; wherein said first sub-target comprises first subsegmentation characteristics for its subsegmented regions and said second sub-target comprises second subsegmentation characteristics for its subsegmented regions, the first subsegmentation characteristics and second subsegmentation characteristics being different in terms of at least one subsegmentation parameter.
2. A substrate according to clause 1, wherein said at least one subsegmentation parameter comprises one or both of: an intended sub-feature width of the sub-features and a number of sub-features per subsegmented region.
3. A substrate according to clause 1 or 2, wherein said plurality of sub-targets comprise at least repetitions of said first sub-target and said second sub-target for each measurement direction in a substrate plane of the substrate.
4. A substrate according to clause 1, 2 or 3, wherein said sub-targets each comprise a pair of periodic structures having a respective periodic structure in each of two layers, each pair of periodic structures comprising said at least said one subsegmented periodic structure.
5. A substrate according to clause 4, wherein said at least said one subsegmented periodic structure comprises the bottom periodic structure in each sub-target.
6. A substrate according to clause 4 or 5, wherein said plurality of targets comprise:
a first pair of sub-targets comprising said first sub-target and said second sub-target; and
a second pair of targets comprising a third sub-target having said first subsegmentation characteristics and a fourth sub-target having said second subsegmentation characteristics.
7. A substrate according to clause 6, wherein the pair of periodic structures in each sub-target have the same pitch; and
there is a deliberate offset difference in the pair of periodic structures between the first pair of sub-targets and second pair of sub-targets.
8. A substrate according to clause 6 or 7, wherein said first pair of sub-targets each have a first deliberate offset and second pair of sub-targets each have a second offset, the first offset and second offset being equal in magnitude and opposite in direction.
9. A substrate according to clause 6, wherein the pair of periodic structures in each sub-target have different pitches, and wherein the order of the gratings is reversed within the target layers between the first pair of sub-targets and second pair of sub-targets.
10. A substrate according to any of clauses 6 to 9, wherein said plurality of sub-targets comprise at least repetitions of said first pair of sub-targets and said second pair of sub-targets for each measurement direction in a substrate plane of the substrate.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The term target should not be construed to mean only dedicated targets formed for the specific purpose of metrology. The term target should be understood to encompass other structures, including product structures, which have properties suitable for metrology applications.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A substrate comprising a target, the target comprising a plurality of sub-targets, the plurality of sub-targets comprising at least a first sub-target and second sub-target, each of the plurality of sub-targets comprising at least one subsegmented periodic structure having repetitions of a first region and a second region, wherein at least one of the first regions or second regions comprise subsegmented regions formed of periodic sub-features;
wherein the first sub-target comprises first subsegmentation characteristics for its subsegmented regions and the second sub-target comprises second subsegmentation characteristics for its subsegmented regions, the first subsegmentation characteristics and second subsegmentation characteristics being different in terms of at least one subsegmentation parameter.

2. The substrate as claimed in claim 1, wherein the at least one subsegmentation parameter comprises one or both of: an intended sub-feature width of the sub-features or a number of sub-features per subsegmented region.

3. The substrate as claimed in claim 1, wherein the plurality of sub-targets comprise at least repetitions of the first sub-target and the second sub-target for each measurement direction in a substrate plane of the substrate.

4. The substrate as claimed in claim 1, wherein the sub-targets each comprise a pair of periodic structures having a respective periodic structure in each of two layers, each pair of periodic structures comprising the at least one subsegmented periodic structure.

5. The substrate as claimed in claim 4, wherein the at least one subsegmented periodic structure comprises the periodic structure of the lower layer of the two layers in each sub-target.

6. The substrate as claimed in claim 4, comprising:
a first pair of sub-targets comprising the first sub-target and the second sub-target; and
a second pair of sub-targets comprising a third sub-target having the first subsegmentation characteristics and a fourth sub-target having the second subsegmentation characteristics.

7. The substrate as claimed in claim 6, wherein the pair of periodic structures in each sub-target have the same pitch; and
there is a deliberate offset difference in the pair of periodic structures between the first pair of sub-targets and second pair of sub-targets.

8. A method of measuring a parameter of interest, the method comprising:
obtaining first measurement data from at least a first sub-target of a target, the first sub-target comprising first subsegmentation characteristics;
determining a first parameter of interest value from the first measurement data;
obtaining second measurement data from at least a second sub-target of the target, the second sub-target comprising second subsegmentation characteristics, the first subsegmentation characteristics and second subsegmentation characteristics being different in terms of at least one subsegmentation parameter;
determining a second parameter of interest value from the second measurement data; and
determining a corrected parameter of interest value from the first parameter of interest value and the second parameter of interest value.

9. The method as claimed in claim 8, wherein the at least one subsegmentation parameter comprises one or both of: an intended sub-feature width of the sub-features or a number of sub-features per subsegmented region.

10. The method as claimed in claim 8, wherein the parameter of interest is overlay.

11. The method as claimed in claim 8, wherein the target comprises a plurality of sub-targets, the plurality of sub-targets comprising the first sub-target and second sub-target, each of the plurality of sub-targets comprising at least one subsegmented periodic structure having repetitions of a first region and a second region, wherein at least one of the first regions or second regions comprise subsegmented regions formed of periodic sub-features.

12. A processing apparatus comprising a processor, and being configured to perform at least the method of claim 8.

13. A metrology apparatus comprising the processing apparatus of claim 12.

14. A non-transient computer program product comprising program instructions therein, the instructions configured to cause performance of at least the method of claim 8, when run on a suitable apparatus.

15. (canceled)

16. The method as claimed in claim 8, wherein there are repetitions of the first sub-target and the second sub-target for each measurement direction in a substrate plane of a substrate having the sub-targets and comprising performing the obtaining and determining using the sub-targets for each measurement direction.

17. The method as claimed in claim 8, wherein the sub-targets each comprise a pair of periodic structures having a respective periodic structure in each of two layers.

18. The method as claimed in claim 17, wherein the periodic structure of the lower layer of the two layers in each sub-target has the first subsegmentation characteristics and/or second subsegmentation characteristics.

19. The substrate according to claim 6, wherein the first pair of sub-targets have a first deliberate offset and the second pair of sub-targets have a second offset, the first offset and second offset being equal in magnitude and opposite in direction.

20. The substrate according to claim 6, wherein the pair of periodic structures in each sub-target have different pitches, and wherein the order of gratings is reversed within the layers between the first pair of sub-targets and second pair of sub-targets.

21. The substrate according to claim 6, wherein the plurality of sub-targets comprise at least repetitions of the first pair of sub-targets and the second pair of sub-targets for each measurement direction in a substrate plane of the substrate.
